(19) United States
(12) Patent Application Publication
(10) Pub. No.: US 2023/0209667 A1
(43) Pub. Date: Jun. 29, 2023

(54) COOKING APPARATUS AND METHOD OF CONTROLLING SAME

(71) Applicant: Samsung Electronics Co., Ltd., Suwon-si (KR)

(72) Inventors: Sangyong LEE, Suwon-si (KR); Jueon KIM, Suwon-si (KR); Jihyung HA, Suwon-si (KR); Kwangyoun KIM, Suwon-si (KR); Kwangryul KIM, Suwon-si (KR)

(21) Appl. No.: 18/176,390

(22) Filed: Feb. 28, 2023

Related U.S. Application Data
(63) Continuation of application No. PCT/KR2021/011878, filed on Sep. 2, 2021.

(30) Foreign Application Priority Data
Sep. 25, 2020 (KR) 10-2020-0125134

(51) Int. Cl. H05B 6/12; H05B 6/06

(52) U.S. Cl. CPC H05B 6/1209; H05B 6/062; H05B 2213/05

(57) ABSTRACT

A cooking apparatus may comprise: an alarm; a cooking plate including glass and a capacitance sensor panel; and a control unit which determines a reference position corresponding to the position of a cooking vessel on the basis of a capacitance change of the cooking plate, determines a plurality of regions on the cooking plate, to which different weights are provided depending on a distance from the reference position, and controls the alarm to output a warning message when a value of capacitance change of the cooking plate having the weights applied thereto exceeds a predetermined value.

### CROSS-REFERENCE TO RELATED APPLICATIONS

This application is a Bypass Continuation of International Patent Application No. PCT/KR2021/011878 filed on Sep. 2, 2021, which claims priority to Korean Patent Application No. 10-2020-0125134 filed on Sep. 25, 2020, in the Korean Intellectual Property Office, the disclosures of which are herein incorporated by reference in their entirety.

### BACKGROUND

### 1. Field

The disclosure relates to a cooking apparatus having a plurality of induction heating coils.

### 2. Description of Related Art

In general, an induction heating cooking apparatus is a cooking apparatus that heats and cooks food using the principle of induction heating. The induction heating cooking apparatus includes a counter on which a cooking vessel is placed and an induction coil that generates a magnetic field with a current applied thereto.

When a magnetic field is generated with a current applied to the induction coil, a secondary current is induced in the cooking vessel, and resistance component of the cooking vessel itself causes Joule heat to be generated. Therefore, the cooking vessel is heated and food contained in the cooking vessel is cooked.

Meanwhile, the induction heating cooking apparatus is provided in the form of a hob including a cooking plate.

On the other hand, when cooking with the cooking apparatus, there may be a case in which food in a cooking vessel overflows.

Even with the food overflow, before it is recognized by a user, a follow-up action may not be taken, and in taking an action, there may be a risk that a user has an accident due to the heated food.

When the food overflows and the user neglects it, excessive overheating may continue and hygiene problems may occur.

The disclosure provides a cooking apparatus for improving safety and convenience by detecting a food overflow in a cooking vessel and notifying a user of the food overflow, and furthermore automatically controlling the cooking apparatus, and a method of controlling the same.

### SUMMARY

A cooking apparatus according to an embodiment includes an alarm; a cooking plate including glass and a capacitive sensor panel; and a controller configured to determine a reference position corresponding to a position of a cooking vessel based on a capacitance change of the cooking plate, determine a plurality of regions on the cooking plate to which different weights are assigned according to distances from the reference position, and in response to a value of the capacitance change of the cooking plate assigned with a weight exceeding a predetermined value, control the alarm to output a warning message.

The controller may be configured to assign a first weight to a first region among the plurality of regions and assigns a second weight less than the first weight to a second region formed at a distance greater than a distance of the first region from the reference position among the plurality of regions.

The controller may be configured to determine a capacitance of the cooking plate corresponding to the cooking vessel as a reference capacitance, and determine a value of a capacitance change of the cooking plate corresponding to each of the plurality of regions based on the reference capacitance.

The controller may be configured to determine coordinate information corresponding to the cooking plate, and associate the reference position and each of the plurality of regions with the coordinate information.

The controller may be configured to obtain first coordinate information of a first point of the cooking plate in which the capacitance is changed at a first time point; obtain second coordinate information of a second point of the cooking plate in which the capacitance is changed at a second time point later than the first time point; and assign a higher weight to the second coordinate information than to the first coordinate information, to determine the value of the capacitance change.

The controller may be configured to determine a contact area of the cooking vessel as an area of the reference position based on the capacitance change of the cooking plate.

The cooking apparatus may further include a heater provided below the cooking plate and provided to heat the cooking vessel, wherein the controller may be configured to, in response to the value of the capacitance change exceeding a predetermined value, decrease an amount of output of the heater.

The heater may include a plurality of induction heating coils, and the controller may be configured to determine the reference position and at least one induction heating coil corresponding to each of the cooking vessels based on the capacitance change of the cooking plate; and in response to a value of the capacitance change corresponding to the at least one induction heating coil exceeding a predetermined value, decrease an amount of output of the at least one induction heating coil.

The cooking apparatus may further include a communicator configured to communicate with a user terminal, wherein the controller may be configured to, in response to the value of the capacitance change exceeding the predetermined value, transmit a warning signal to the user terminal.

The controller may be configured to, in response to the value of the capacitance change exceeding the predetermined value, transmit an interface for controlling the cooking apparatus to the user terminal.

The cooking plate may include the capacitive sensor panel stacked on an upper surface of the glass; and a deterioration protection layer stacked on an upper surface of the capacitive sensor panel.

A method of controlling a cooking apparatus according to an embodiment includes determining a reference position corresponding to a position of a cooking vessel based on a capacitance change of a cooking plate; determining a plurality of regions on the cooking plate to which different weights are assigned according to distances from the reference position; and in response to a value of the capacitance change of the cooking plate assigned with a weight exceeding a predetermined value, controlling the alarm to output a warning message.

The determining of the plurality of regions on the cooking plate may include assigning a first weight to a first region among the plurality of regions; and assigning a second weight less than the first weight to a second region formed at a distance greater than a distance of the first region from the reference position among the plurality of regions.

The determining of the value of the capacitive change of the cooking plate may include determining a capacitance of the cooking plate corresponding to the cooking vessel as a reference capacitance; and determining a value of a capacitance change of the cooking plate corresponding to each of the plurality of regions based on the reference capacitance.

The method may further include determining coordinate information corresponding to the cooking plate; and associating the reference position and each of the plurality of regions with the coordinate information.

The determining of the value of the capacitive change of the cooking plate may include obtaining first coordinate information of a point of the cooking plate in which the capacitance is changed at a first time point; obtaining second coordinate information of a point of the cooking plate in which the capacitance is changed at a second time point later than the first time point; and assigning a higher weight to the second coordinate information than to the first coordinate information, to determine the value of the capacitance change.

The method may further include determining a contact area of the cooking vessel as an area of the reference position based on the capacitance change of the cooking plate.

The method may further include, in response to the value of the capacitance change exceeding a predetermined value, decreasing an amount of output of the heater.

The method may further include determining the reference position and at least one induction heating coil corresponding to each of the cooking vessels based on the capacitance change of the cooking plate.

The decreasing of the amount of the heater may include, in response to a value of the capacitance change corresponding to the at least one induction heating coil exceeding a predetermined value, decreasing an amount of output of the at least one induction heating coil.

The method may further include, in response to the value of the capacitance change exceeding the predetermined value, transmitting a warning signal to the user terminal.

The method may further include, in response to the value of the capacitance change exceeding the predetermined value, transmitting an interface for controlling the cooking apparatus to the user terminal.

A cooking apparatus according to an embodiment includes an alarm; a heater including at least one induction heating coil; a cooking plate including glass and a capacitive sensor panel stacked to corresponding to an entire area of an upper surface of the glass; and a controller configured to, in response to a cooking vessel being placed on the cooking plate, determine a reference position corresponding to a position of the cooking vessel based on a capacitance change of the cooking plate, determine a first region having a first radial distance from the reference position, determine a second region having a second radial distance greater than the first radial distance from the reference position, assign a first weight to the first region, and assign a second weight to the second region, and in response to the capacitive change value of the cooking plate assigned the first weight and the second weight exceeding a predetermined value, determine that food overflows from the cooking vessel to the cooking plate,

The controller according to an embodiment may control the alarm to output a warning message.

The cooking apparatus according to an embodiment may further include a heater including a plurality of induction heating coils,

An upper surface of the cooking plate may include heating regions corresponding to the induction heating coils and non-heating regions other than the heating regions, and

The controller may be configured to, in response to the cooking vessel being placed on the non-heating region, determine a reference position corresponding a position of the cooking vessel based on a capacitive change of the cooking plate on the non-heating region.

The cooking apparatus according to an embodiment and the method of controlling the same can improve safety and convenience by detecting a food overflow in a cooking vessel and notifying a user of the food overflow, and furthermore automatically controlling the cooking apparatus.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a diagram schematically illustrating an external appearance of a cooking apparatus according to an embodiment;

FIG. 2 is a diagram schematically illustrating the inside of a cooking apparatus according to an embodiment;

FIG. 3 is a control block diagram according to an embodiment;

FIG. 4 is a diagram for describing an operation of determining a reference position and an operation of determining coordinate information according to an embodiment;

FIG. 5 is a diagram for describing a plurality of regions having different weights on a cooking plate according to an embodiment;

FIG. 6 is a diagram for describing an operation of a plurality of regions being changed according to an embodiment;

FIG. 7 is a diagram for describing an operation of determining that food has not overflowed even with a change in capacitance according to an embodiment;

FIGS. 8A and 8B are diagrams for describing an operation of controlling a heating module in response to an overflow of a plurality of food items according to an embodiment;

FIG. 9 is a diagram for describing an operation of transmitting a warning message to a user terminal by a cooking apparatus according to an embodiment;

FIGS. 10 and 11 are diagrams for describing an operation in which a cooking apparatus transmits an interface to a user terminal according to an embodiment;

FIGS. 12 and 13 are schematic diagrams illustrating a cooking plate according to an embodiment; and

FIG. 14 is a flow chart according to an embodiment.

### DETAILED DESCRIPTION

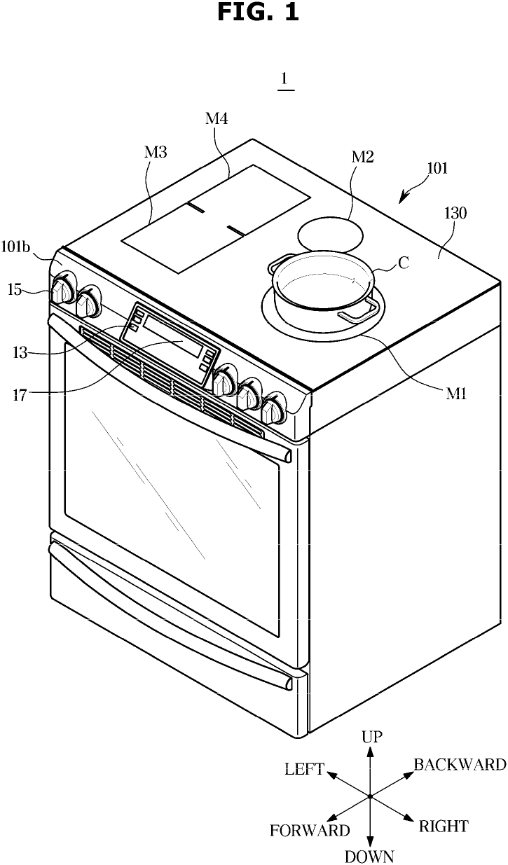

FIGS. 1 through 14, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

Like numerals refer to like elements throughout the specification. Not all elements of embodiments of the disclosure will be described, and description of what are commonly known in the art or what overlap each other in the embodiments will be omitted. The terms as used throughout the specification, such as “~ part”, “~ module”, “~ member”, “~ block”, etc., may be implemented in software and/or hardware, and a plurality of “~ parts”, “~ modules”, “~ members”, or “~ blocks” may be implemented in a single element, or a single “~ part”, “~ module”, “~ member”, or “~ block” may include a plurality of elements.

It will be further understood that the term “connect” or its derivatives refer both to direct and indirect connection, and the indirect connection includes a connection over a wireless communication network.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements,

In the specification, it will be understood that, when a member is referred to as being “on/under” another member, it may be directly on/under the other member, or one or more intervening members may in addition be.

Although the terms “first,” “second,” “A,” “B,” etc. may be used to describe various components, the terms do not limit the corresponding components, but are used only for the purpose of distinguishing one component from another component.

As used herein, the singular forms “a,” “an” and “the” are intended to include the plural forms as well, unless the context clearly indicates otherwise.

Reference numerals used for method steps are just used for convenience of explanation, but not to limit an order of the steps. Thus, unless the context clearly dictates otherwise, the written order may be practiced otherwise.

Hereinafter, the principles and embodiments of the disclosure will be described with reference to the accompanying drawings.

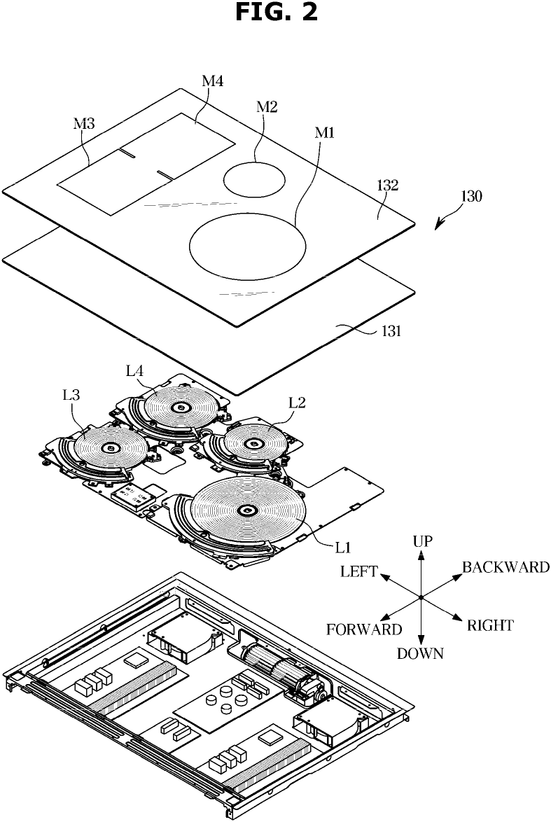

FIG. 1 is a diagram schematically illustrating an external appearance of a cooking apparatus according to an embodiment, and FIG. 2 is a diagram schematically illustrating the inside of a cooking apparatus according to an embodiment.

Referring to FIGS. 1 and 2, the cooking apparatus 1 includes a main body 101 forming an exterior of the cooking apparatus 1 and accommodating various components constituting the cooking apparatus 1 therein.

On an upper surface of the main body 101, a cooking plate 130 on which to place a cooking vessel C may be provided. Glass forming the cooking plate 130 may be implemented as tempered glass, such as ceramic glass, so as not to be easily damaged, but is not limited thereto, and may be implemented with various known materials.

In addition, on an upper surface of the cooking plate 130, guide marks may be provided so that the user may place the cooking vessel in an appropriate position. For example, as shown in FIG. 1, a plurality of guide marks M1, M2, M3, and M4 for guiding the user to the position of the cooking vessel C may be formed.

At a lower side of the cooking plate 130, at least one induction heating coil for generating a magnetic field may be provided. For example, as shown in FIG. 2, the cooking apparatus 1 may be provided with a plurality of induction heating coils L1, L2, L3, and L4. The plurality of induction heating coils L1, L2, L3, and L4 may be provided at positions corresponding to the guide marks M1, M2, M3, and M4, respectively.

In addition, on a front surface 101b of the main body 101, a manipulation dial 13, a manipulation button 15, and a display 17 for receiving a control command from the user or displaying various types of information may be provided.

Meanwhile, the cooking apparatus 1 according to the embodiment may include four induction heating coils L1, L2, L3, and L4, but is not limited thereto, and the cooking apparatus 1 may include three or less, or five or more induction heating coils.

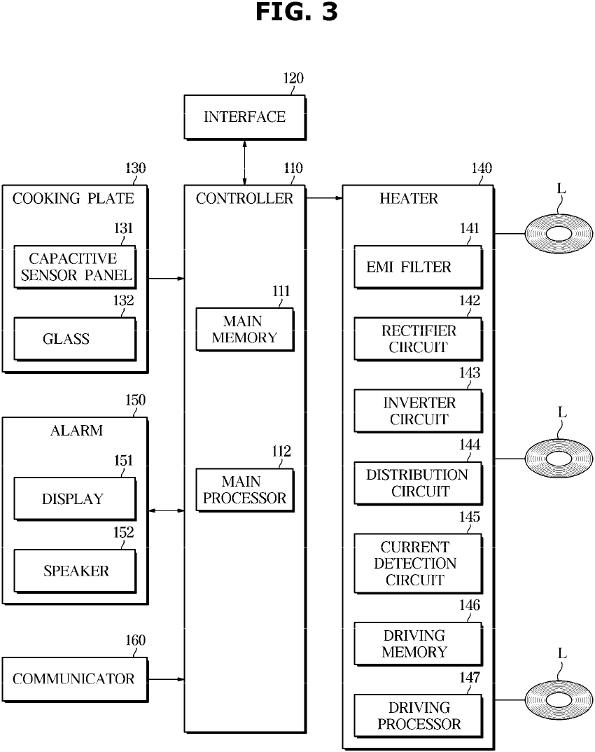

FIG. 3 is a control block diagram according to an embodiment.

Referring to FIG. 3, the cooking apparatus 1 may include a plurality of induction heating coils L, a controller 110, a user interface 120, a cooking plate 130, a heater 140, and an alarm 150.

The cooking plate 130, the heater 140, and the controller 110 may be operated by a processor.

The cooking plate 130, the heater 140, and the controller 110 may be separately implemented.

According to an embodiment, at least one of the cooking plate 130, a temperature detector, the heater 140, and the controller 110 may be implemented to be integrated into a System On Chip (SOC) provided in the cooking apparatus 1.

However, since the cooking apparatus 1 may not be provided only one SOC, it is not limited that components are integrated into one SOC.

That is, the above-described components in the cooking apparatus 1 may be provided in a plurality of printed circuit board assemblies or integrated, without limitation.

Hereinafter, components in the cooking apparatus 1 will be individually described.

The user interface 120 may include a touch panel and input buttons that receive a touch input from a user or display various types of information about the cooking apparatus 1. Meanwhile, as for the touch panel, a capacitive sensor panel may perform the function of the touch panel.

The user interface 120 may receive a control command from a user and output an electrical signal corresponding to the user’s control command to the controller 110. In addition, the user interface 120 may receive various types of information about the cooking apparatus 1 from the controller 110.

The user interface 120 may receive a touch input from the user and transfer the touch input to the controller 110. In addition, the user interface 120 may display various types of information about the cooking apparatus 1, such as operation state information of the cooking apparatus 1. The user interface 120 may be provided employing a touch screen type display panel previously known in the art, and there is no limitation on this.

The user interface 120 may receive a user’s touch input for selecting a cooking vessel C, and transfer the received touch input to the controller 110. For example, upon receiving an output-up command of the cooking apparatus 1 from a user through the user interface 120, the user interface 120 may output the output-up command to the controller 110. Detailed descriptions of the controller 110 will be described below.

The user interface 120 may include a plurality of buttons that receive a control command from a user and output an electrical signal corresponding to the user’s control command to the controller 110. For example, the user interface 120 may include an operation button for receiving a power on/off command of the cooking apparatus 1, and a power up button and a power down button for receiving the strength of the magnetic field and/or electromagnetic field output from the cooking apparatus 1.

Various well-known types of buttons (or switches), such as a push button, a slide button, a toggle button, a touch button, and a dial, may be used as the user interface 120, and there is no limitation on this.

The cooking plate 130 may include a capacitance sensor panel 131 and glass 132.

According to certain embodiments, the capacitance sensor panel 131 may be provided on the lower side of the glass 132.

The capacitance sensor panel 131 may detect the capacitance of the cooking plate. In this case, there is no limitation on a method of detecting the capacitance by the capacitance sensor panel 131.

For example, the capacitance sensor panel 131 may detect capacitance through a self-capacitance method of directly detecting a capacitance value using a capacitor provided between each end of an electrode pair, that is, a plurality of electrodes.

As another example, the capacitance sensor panel 131 may detect capacitance by applying a reference voltage to one of a plurality of electrodes and detecting a capacitance between the plurality of electrodes that changes in response to an approaching cooking vessel C.

In addition, the capacitance sensor panel 131 may employ various known methods of detecting capacitance, and there is no limitation on this.

The glass 132 may be implemented with tempered glass, such as ceramic glass, but is not limited thereto, and may be implemented with various materials known in the art.

In addition, according to another embodiment, a deterioration protection layer may be additionally included. Details of the deterioration protective layer will be described below.

The cooking apparatus 1 may be provided with a heater 140.

The heater 140 may receive power from an external power source, and according to a driving control signal from the controller 110, supply current to the induction heating coil L. For example, the heater 140 may selectively supply a driving current to the plurality of induction heating coils L according to an output intensity output by the controller 110.

The heater 140 may include an electromagnetic interference (EMI) filter 141, a rectifier circuit 142, an inverter circuit 143, a distribution circuit 144, a current detection circuit 145, a driving memory 146, and a driving processor 147.

In addition, the cooking apparatus may include an alarm 150.

The alarm 150 may include a display 151 indicating various states of the cooking apparatus. Such a display may output a warning message based on the control of the controller. In addition, the alarm 150 may include a speaker 152 outputting a warning signal as an audible signal.

Meanwhile, the controller 110 may include a main memory 111 and a main processor 112.

The controller 110 may determine a reference position corresponding to the position of a cooking vessel based on the capacitance change of the cooking plate.

That is, when a cooking vessel is placed on the cooking apparatus, the capacitance of the corresponding portion is changed, based on which the controller may detect that a cooking vessel is placed at the corresponding position.

The controller 110 may determine a plurality of regions on the cooking plate to which different weights are assigned according to distances from the reference position.

Specifically, the cooking plate 130 may be matched with the coordinate information, and the controller may divide a plurality of regions based on the cooking vessel and assign different weights to the corresponding regions.

Assigning of a weight, as will be described below, may refers to, when determining an overflow based on a capacitance generated in a region, a contribution degree to which the corresponding data contributes to the determination.

The controller 110 may control the alarm 150 to output a warning message when a capacitance change of the cooking plate assigned with the weight exceeds a predetermined value.

The controller 110 assigns a first weight to a first region among the plurality of regions, and assigns a second weight lower than the first weight to a second region formed at a distance greater than a distance of the first region from the reference position among the plurality of regions.

That is, a region relatively close to the reference position may be determined as a first region, and a first weight may be assigned to the first region.

On the other hand, a region relatively far from the reference position may be determined as a second region and a second weight may be assigned to the second region.

The controller 110 may determine a capacitance of the cooking plate corresponding to the cooking vessel as a reference capacitance, and determine a capacitance change value of the cooking plate corresponding to each of the plurality of regions based on the reference capacitance.

Since there may be a difference between a capacitance when a cooking vessel is not placed on the cooking plate and a capacitance when a cooking vessel is placed on the cooking plate, the capacitance when the cooking vessel is placed may be determined as a reference capacitance, and then a capacitance change value may be determined.

The controller 110 may determine coordinate information corresponding to the cooking plate. In addition, the controller may associate the reference position and each of the plurality of regions with coordinate information. Detailed description thereof will be described below.

The controller 110 may obtain first coordinate information of a point in which the capacitance is changed on the cooking plate at a first time point and obtain second coordinate information of a point in which the capacitance is changed on the cooking plate at a second time point later than the first time point, and assign a higher weight to the second coordinate information than the first coordinate information, to determine a capacitance change value.

Detailed operations of determining a food overflow based on changes in capacitance at different time points will be described below.

The controller 110 may determine a contact area of the cooking vessel based on the capacitance change of the cooking plate and determine the contact arear as an area of the reference position.

That is, since the cooking vessel has an area, the controller 110 may consider the area of the cooking vessel to determine the reference position.

The controller 110 may decrease the amount of output of the heater when the change in capacitance exceeds a predetermined value.

That is, when an overflow of food in the cooking vessel occurs, the controller 110 may control to decrease the output amount of the heater so that the food does not boil any more.

The controller 110 may determine the reference position and at least one induction heating coil corresponding to each of the plurality of cooking vessels based on the capacitance change of the cooking plate.

When cooking is performed with a plurality of cooking vessels, the controller may determine an induction heating coil for heating the cooking vessel at the corresponding position based on a change in capacitance of the corresponding portion.

The controller 110 may, upon determining a region as described above, when a capacitance change value of an induction heating coil corresponding to the region exceeds a predetermined value, reduce the amount of output of the corresponding induction heating coil. Details thereof will be described below.

In addition, the cooking apparatus according to an embodiment may further include a communicator communicating with a user terminal.

The communicator 160 may include one or more components that enable communication with an external device, and for example, may include at least one of a short-range communication module, a wired communication module, and a wireless communication module.

The short-range communication module may include various short-range communication modules that transmit and receive signals using a wireless communication network in a short range, such as a Bluetooth module, an infrared communication module, a radio frequency identification (RFID) communication module, a wireless local access network (WLAN) communication module, an NFC communication module, and a Zigbee communication module.

The wireless communication module may include wireless communication modules supporting various wireless communication methods, such as a Wifi module, a wireless broadband module (Wibro) module, a global system for mobile communication (GSM) module, a code division multiple access (CDMA) module, a wideband code division multiple access (WCDMA) module, a universal mobile telecommunications system (UMTS) module, a time division multiple access (TDMA) module, a long term evolution (LTE) module, and the like.

The controller 110 may, in response to the capacitance change value exceeding a predetermined value, transmit a warning signal to the user terminal.

The user terminal, may upon receiving the warning signal, output a warning message on the display of the user terminal.

The controller 110 may, in response to the capacitance change value exceeding a predetermined value, transmit an interface for controlling the cooking apparatus to the user terminal. The user terminal may, upon receiving the interface, provide the user with an interface in the form of a graphical user interface (GUI), based on which the user may control the cooking apparatus.

The main processor 112 may generate a control signal based on data stored in the main memory 111 and control components in the cooking apparatus 1 using the generated control signal.

The main memory 111 may store control programs and control data for controlling the operation of the cooking apparatus 1. In addition, the main memory 111 may temporarily store various control commands input through the user interface 120 and position data of the cooking vessel received from the capacitance sensor panel 131.

In addition, the main memory 111 may provide a control program and/or control data to the main processor 112 according to a control signal from the main processor 112, or provide input control commands, position data of the cooking vessel and/or temperature data of the cooking vessel to the main processor 112.

The main memory 111 may include volatile memories, such as SRAM and DRAM that may temporarily store data. In addition, the main memory 111 may include non-volatile memories, such as an ROM, an EPROM, an EPROM, and a flash memory, that may store control programs and/or control data for a long period of time.

The main processor 112 may include various logic circuits and arithmetic circuits, process data according to programs provided from the main memory 111, and generate control signals according to processing results.

At least one component may be added or omitted to correspond to the performances of the components of the cooking apparatus 1 shown in FIG. 3. In addition, it should be easily understood that the mutual positions of the components may be changed to correspond to the performance or structure of the system.

Meanwhile, each component shown in FIG. 3 refers to a software component and/or a hardware component, such as a Field Programmable Gate Array (FPGA) and an Application Specific Integrated Circuit (ASIC).

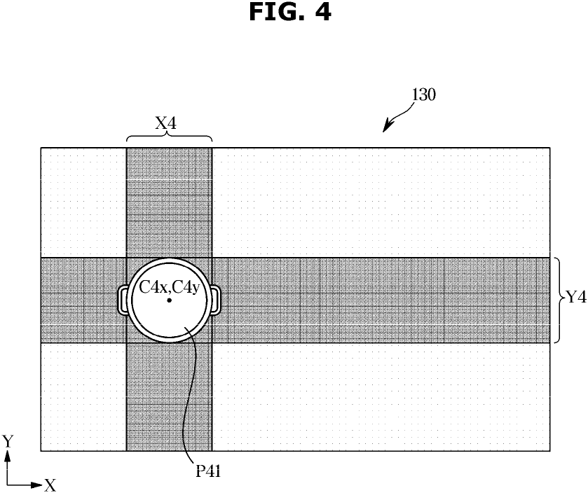

FIG. 4 is a diagram for describing an operation of determining a reference position and an operation of determining coordinate information according to an embodiment.

Referring to FIG. 4, the controller may determine coordinate information corresponding to the cooking plate.

As shown in FIG. 4, the controller may interpret the upper surface of the cooking plate of the cooking apparatus based on XY coordinates.

Meanwhile, the controller may, upon a cooking device being placed on the cooking plate, detect a change in capacitance, and determine a position P41 of the pot based on the change in capacitance.

The controller may, based on a cooking vessel being initially placed on the cooking plate, detect the size and area of the cooking vessel and perform calibration.

In FIG. 4, a region of the cooking plate occupied by the pot may be determined as P41 and the corresponding region may be determined as a reference position.

Specifically, the controller measures the electrode positions of X and Y axes of the capacitance sensor panel to measure the coordinates in which a capacitance change has occurred.

In addition, the controller may determine the capacitance of the cooking plate corresponding to the cooking vessel as a reference capacitance.

That is, the capacitance of the region P41 may be determined as a capacitance of the cooking vessel in a state in which food is not overflowing. In addition, the capacitance of the region other than P41 may be determined as a capacitance in a state in which food is not overflown, in a region in which no cooking vessel is provided.

The controller may determine the cooking vessel contact area based on the change in capacitance of the cooking plate.

In FIG. 4, the cooking vehicle is located at cooking plate coordinates (C4x, C4y), but the cooking vehicle due to having an area may occupy an area of X4 in the horizontal direction and Y4 in the vertical direction.

Therefore, the controller may determine that the cooking vessel having a diameter of X4 is located in a region in which X4 and Y4 overlap each other.

Meanwhile, in determining such coordinate information, the capacitance sensor panel may be provided in a mesh form.

Meanwhile, the operation described in FIG. 4 is only one embodiment of determining the coordinate information of the disclosure, and there is no limitation on the operation of deriving the coordinate information.

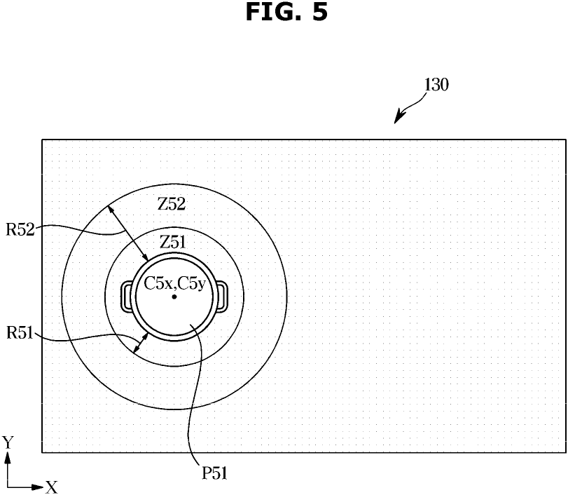

FIG. 5 is a diagram for describing a plurality of regions having different weights on a cooking plate according to an embodiment.

Referring to FIG. 5, the controller may determine a reference position corresponding to the position of the cooking vessel based on the capacitance change of the cooking plate.

The controller may, based on the above-described operation, determine that the cooking vessel is provided at (C5x, C5y).

Meanwhile, the controller may determine that the area of the cooking vessel is P51 and determine the corresponding region as a reference position.

In addition, the controller may determine a region of a radial distance R51 from the reference position P51 as a first region Z51.

In addition, the controller may determine a region of a radial distance R52 from the reference position P51 as a second region Z52.

Meanwhile, the controller may assign different weights to the first region and the second region.

According to certain embodiments, the first region may have a radial distance of 3 cm from the region of the detected cooking vessel.

Meanwhile, the first weight assigned to the first region may be determined to be greater than the second weight assigned to the second region. Descriptions thereof are provided below.

Meanwhile, the operation described in FIG. 5 is only one embodiment of determining a plurality of regions based on the cooking vessel of the disclosure, and there is no limitation on the operation of determining a reference position and a plurality of regions.

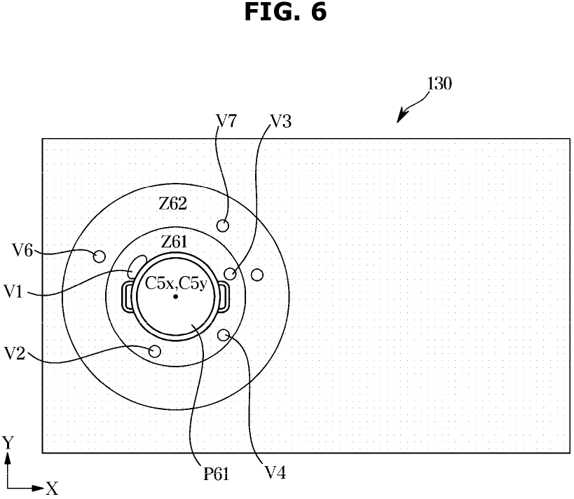

FIG. 6 is a diagram for describing an operation of capacitance being changed in a plurality of regions according to an embodiment.

In FIG. 6, a situation in which the cooking vessel is located at a point P61 and food overflows from the cooking vessel is illustrated.

Referring to FIG. 6, a first region Z61 has regions V1, V2, V3, and V4 stained with food overflowing from the cooking vessel.

In addition, a second region Z62 has regions V5 and V6 stained with food.

In this case, as described above, the controller assigns a weight based on each radial distance from the cooking vessel. Specifically, the controller may assign an immediate vicinity of the cooking vessel a large weight to detect an overflow of the cooking vessel, and may determine a capacitance change in a distant region which is not frequently occur as a water drop from the consumer’s hand or other cooking utensils and assign a smaller weight in the determination.

In addition, the controller may track the position P61 of the cooking vessel wherever the cooking vessel is placed on the cooking plate since the capacitive sensor panel is installed over the entire area of the top of the cooking plate, and may assign a weight based on the position P61 of the cooking vessel.

The controller may obtain first coordinate information of a point in which the capacitance is changed on the cooking plate at a specific time point and obtain second coordinates of a point in which the capacitance is changed on the cooking plate at a second time point later than the first time point, and assign a higher weight to the second coordinate information than the first coordinate information, to determine a capacitance change value.

Such an operation may be performed based on Equation 1 below.

$${A}_{k} = {A}_{k - 1} + \frac{{A}_{k} - {A}_{k - n}}{n}$$

Referring to Equation 1, Aₖ may indicate a change in capacitance data of a first region Z61.

On the other hand, Aₖ may indicate a capacitance change at the last time point, Aₖ₋₁ may indicate a capacitance change at an immediately previous time point, and Aₖ₋ₙ may indicate a capacitance change at the first time point.

For example, the controller may, upon assuming that the change in capacitance of the region V1 in FIG. 6 has occurred at a nearer time point than the change in capacitance of the region V4, determine a final capacitance change value by considering more of the change in capacitance of the region V1 based on Equation 1.

$${B}_{k} = {B}_{k - 1} + \frac{{B}_{k} - {B}_{k - n}}{n}$$

Referring to Equation 2, Bₖ may indicate a change in capacitance data of the second region Z62.

Meanwhile, Bₖ may indicate a change in capacitance at the last time point, Bₖ₋₁ may indicate a change in capacitance at an immediately previous time point, and Bₖ₋ₙ may indicate a change in capacitance at the first time point.

For example, the controller may, under assuming that the change in capacitance of the region V5 in FIG. 6 has occurred at a nearer time point than the change in capacitance of the region V6, determine a final capacitance change value by considering more of the change in capacitance of the V5 based on Equation 2.

Meanwhile, the controller may finally determine the capacitance change value of the cooking plate based on Equation 3.

$${P}_{k} = {W}_{A} \times {A}_{k} + {W}_{B} \times {B}_{k}$$

Referring to Equation 3, Pₖ may indicate a capacitance change value of the cooking plate, W_{A} may indicate a first weight assigned to the first region, and W_{B} may indicate a second weight assigned to the second region.

Meanwhile, the first weight may be determined as a value greater than the second weight. Accordingly, the capacitance change value of the first region may be more influential than the capacitance change value of the second region in determining the final capacitance change value.

That is, when the controller determines a water overflow situation, the regions V1, V2, V3, and V4 may be more influential than the regions V5 and V5 may be.

Meanwhile, the controller may, in response to the determined capacitance change value exceeding a predetermined value, control the alarm 150 to output a warning message. In addition, as will be described below, the controller may transmit a warning signal to the user terminal or limit the output of the heater in this situation.

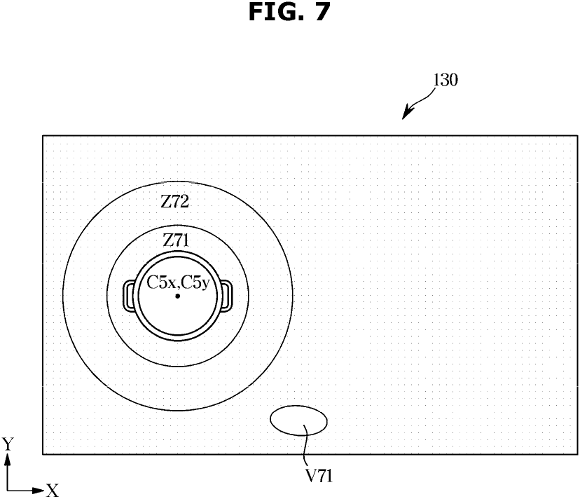

FIG. 7 is a diagram for describing an operation of determining that food has not overflowed even with a change in capacitance according to an embodiment.

Referring to FIGS. 6 and 7, FIG. 7 illustrates a case in which a change in capacitance has occurred in a second region Z72 rather than in a first region Z71 unlike FIG. 6. In this case, a change in capacitance in a region, such as V71, is not easily interpreted as food in the cooking vessel overflowing and reaching the cooking plate. That is, even in a situation in which a user puts his/her hand on the cooking plate or liquid other than food in the cooking vessel exists on the cooking plate, capacitance change may occur. In response to a capacitance change occurring in such a region, the region is not assigned a high weight, unlike the first region, resulting in a derived capacitance change value that does not exceed a predetermined value.

That is, referring to Equation 3, in the situation of FIG. 7, only Bk exists and Bk may be assigned a weight WB smaller than a weight WA, so that the final charge capacity change value Pk may not exceed a predetermined value.

Accordingly, in this case, the controller may determine that an overflow situation has not occurred.

Meanwhile, the operations described in FIGS. 6 and 7 are only one embodiment of the disclosure, and there is no limitation on the operation of determining the capacitance change value by assigning different weights according to regions and time points by the controller.

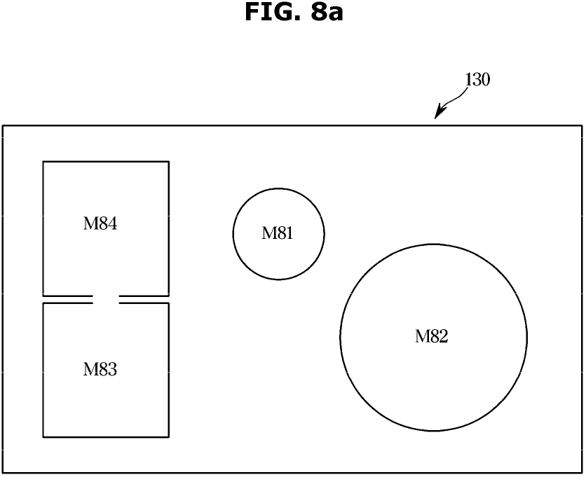

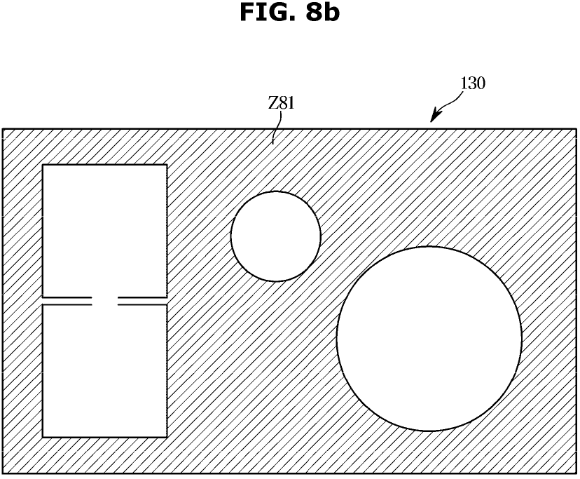

FIGS. 8A and 8B are diagrams for describing an operation of controlling a heating module in response to an overflow of a plurality of food items according to an embodiment.

Referring to FIG. 8A, the cooking apparatus may further include a heater provided below the cooking plate and provided to heat a cooking vessel.

The controller may, in response to the capacitance change value exceeding a predetermined value, decrease an amount of output the heater.

As described above, the heater may include a plurality of induction heating coils (L1, L2, L3, and L4 in FIG. 2). In addition, the top plate of the cooking plate may include regions corresponding to induction heating coils, respectively.

Specifically, the upper surface of the cooking plate may include heating regions corresponding to the induction heating coils and non-heating regions other than the heating regions.

In FIGS. 8A and 8B, heating regions M81, M82, M83, and M84 corresponding to the respective induction heating coils provided in the heater are illustrated.

Meanwhile, the other region, that is, a region Z81 is a region that does not correspond to an induction heating coil.

Meanwhile, according to an embodiment of the disclosure, the entire upper surface of the cooking plate 130 is provided by stacking a capacitive sensor panel. Therefore, even when a cooking vessel is placed on the upper surface of the cooking plate 130 that does not correspond to the induction heating coil, the cooking apparatus may detect the existence of the corresponding cooking vessel.

The controller may determine the reference position and at least one induction heating coil corresponding to each of the plurality of cooking vessels based on a capacitance change of the cooking plate 130.

For example, when a user places a cooking vessel in M81, which is a heating region, the controller determines that the cooking vessel is provided in the corresponding region based on a change in capacitance, determine the corresponding region as a reference position, and then perform an operation of determining a food overflow based on the above-described operation.

In addition, when a capacitance change value corresponding to the at least one induction heating coil exceeds a predetermined value, the controller may reduce an output amount of the at least one induction heating coil.

Meanwhile, the controller may drive the plurality of induction heating coils according to the size of the cooking vessel.

Specifically, when the size of the cooking vessel is large, the user may place the cooking vessel over the heating regions M83 and M84.

Since the capacitance sensor panel is provided over the entire area of the cooking plate, the controller may, even in response to the cooking vessel being located in the regions, determine that the cooking vessel is placed in positions corresponding thereto.

In addition, the controller may drive all of the induction heating coils corresponding to the regions M83 and M84.

In this case, the controller may determine the region M83 and the region M84 as reference positions, and determine whether food overflows from the cooking vessel based on the above-described operation.

Referring to FIG. 8B, since the capacitance sensor panel is provided over the entire area of the cooking plate, even when the cooking vessel is placed in a region that does not correspond to an induction heating coil, that is, the non-heating region Z81, the presence of the cooking vessel and the overflow of food etc. may be determined.

For example, even when a cooking vessel is placed in the region Z81, which is a region of the cooking plate that does not correspond to an induction heating coil, the controller may detect the presence of the cooking vessel based on the change in capacitance of the corresponding region and determine the corresponding region as a reference position and determine whether food is overflown.

Meanwhile, the operations described in FIGS. 8A and 8B are only one embodiment of the disclosure, and there is no limitation on an operation of controlling induction heating coils in a plurality of regions and an operation of detecting a cooking vessel in a region not corresponding to an induction heating coil and detecting a food overflow.

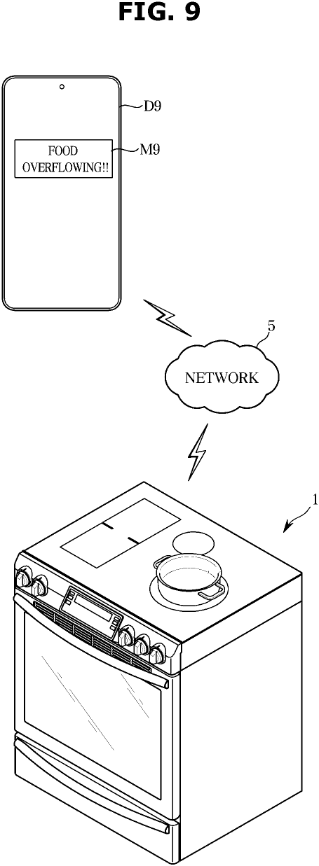

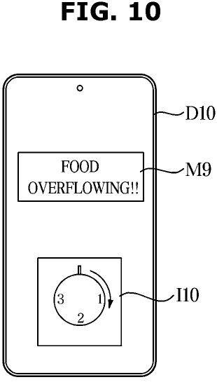

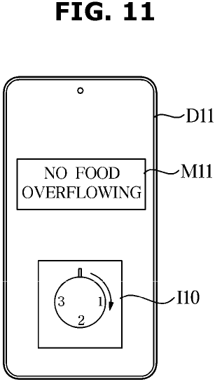

FIG. 9 is a diagram for describing an operation in which a cooking apparatus transmits a warning message to a user terminal according to an embodiment, and FIGS. 10 and 11 are diagrams for describing an operation in which a cooking apparatus transmits an interface to a user terminal according to an embodiment.

The cooking apparatus may include a communicator that communicates with a user terminal D9.

The user terminal D9 may refer to any device having a user interface and capable of accessing a server.

The user terminal may be implemented as a computer or a portable terminal capable of connecting to the apparatus through a network. Here, the computer may include, for example, a notebook computer, a desktop computer, a laptop PC, a tablet PC, a slate PC, and the like, each of which is equipped with a WEB Browser. The portable terminal is a wireless communication device mobility, and may include all types of handheld based wireless communication devices, such as a personal communication system (PCS), a global system for mobile communications (GSM), a personal digital cellular (PDC), a personal handyphone system (PHS), a personal digital assistant (PDA), an international mobile telecommunication (IMT)-2000, a code division multiple access (CDMA)-2000, a w-code division multiple access (W-CDMA), a wireless broadband internet (WiBro) terminal, a smart Phone, and the like; and wearable devices, such as a watch, a ring, a bracelet, an anklebracelet, a necklace, glasses, a contact lens, or a head-mounted-device (HMD).

The cooking apparatus 1 and the user terminal D9 may communicate through a network 5.

In this case, the network 5 may refer to a wireless communication network, and may include at least one of a telecommunication network, for example, a computer network (e.g., LAN or WAN), the Internet, or a telephone network.

Such a network 5 may be provided to the cooking apparatus 1 and the user terminal through an access point (AP). In addition, the cooking apparatus 1 and the user terminal may form an Internet of Things (IoT) environment through an access relay.

Meanwhile, the user interface provided by the user terminal D9 may include a display for providing various types of information to the user, and for example, may include a touch screen that provides various types of information to the user and receives a touch input from the user.

Referring to FIG. 9, the cooking apparatus 1 may further include a communicator communicating with the user terminal D9 as described above.

In addition, the controller of the cooking apparatus 1 may, in response to the capacitance change value exceeding a predetermined value, transmit a warning signal to the user terminal.

According to an embodiment, the user terminal D9 may, upon receiving a warning signal from the cooking apparatus 1, output a warning message on a display provided in the user terminal. According to an embodiment, the user terminal may output a warning message M9, such as “Food overflowing!!!” on a display provided in the user terminal.

Meanwhile, the type of the warning message that may be output by the user terminal D9 is not limited, and the warning message may be output in the form of text as shown in FIG. 9 or a specific image.

In addition, in general, the user terminal D9 may be provided with a speaker so that a warning message may be output in the form of a sound.

Meanwhile, referring to FIGS. 10 and 11, the controller of the cooking apparatus 1 may, in response to the capacitance change value determined based on the above-described operation exceeding a predetermined value, transmit an interface I10 for controlling the cooking apparatus 1 to the user terminal D10.

Meanwhile, the user terminal D10 may output the corresponding interface I10 on the display, similar to FIG. 9. The interface presented in FIG. 10 is to control the output of the heater of the cooking apparatus D10, and the user may control the output of the heater of the cooking apparatus using the interface.

In detail, the user terminal D10 may transmit and receive signals to and from the cooking apparatus 1 through the above-described network. Accordingly, when a user inputs a command for controlling the cooking apparatus 1 to an interface output on the user terminal, the user terminal may transmit the command to the cooking apparatus 1 to control the cooking apparatus 1.

Specifically, when the user changes the output to level 1 using the interface I10, the output may be reduced.

Meanwhile, in this case, the user terminal D10 may transmit a control signal to the cooking apparatus, and the cooking apparatus 1 may receive the control signal and reduce the output of the heater again. Meanwhile, when food no longer overflows from the cooking vessel as a result of reducing the output of the heater, the cooking apparatus may transmit state information of the cooking apparatus to the user terminal. That is, when the cooking vessel no longer overflows with food as a result of lowering the output of the heater, a status message M11, such as “food is not overflowing” may be output to the display provided in the user terminal D11.

In FIGS. 10 and 11, a situation in which food stops from overflowing as a result of a user changing the output to level 1 is illustrated. However, when food continues to overflow even after the user controls the cooking apparatus using the user terminal, the controller of the cooking apparatus may continuously output a warning signal and the user terminal may receive the warning signal and output a warning message.

Meanwhile, the operations presented in FIGS. 9 to 11 are only one embodiment of the disclosure, and the operation of exchanging signals between the cooking apparatus and the user terminal to inform the user of a food overflow situation and the user controlling the cooking apparatus based on the situation is limited.

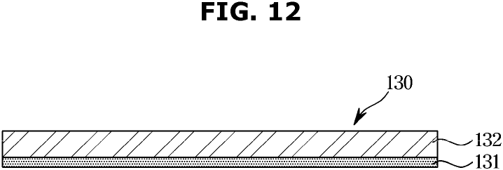

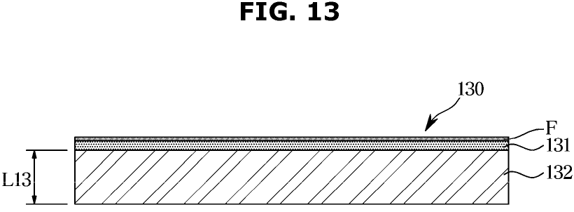

FIGS. 12 and 13 are schematic diagrams illustrating a cooking plate in an embodiment.

Referring to FIG. 12, the cooking plate may be provided with glass and a capacitive sensor panel.

Referring to FIG. 12, the cooking plate 130 may include a glass 132 and a capacitance sensor panel 131.

As described above, the glass 132 may be implemented with tempered glass, such as ceramic glass, but is not limited thereto, and may be implemented with various materials known in the art.

Meanwhile, the capacitance sensor panel 131 may be provided on the entire area of the cooking plate.

That is, the capacitive sensor panel may be disposed on the upper surface of the cooking plate to detect food overflowing to a portion of the upper surface of the cooking apparatus so that the cooking apparatus may automatically operate.

Specifically, in a state in which indium tin oxide (ITO) electrodes are arranged below the glass 132 along the X and Y axes of the capacitance sensor panel, positions of an electrode on each axis are measured, and a position in which a capacitance change has occurred may be transmitted to the controller, based on which the controller may determine coordinate information of the corresponding portion.

Referring to FIG. 13, according to an embodiment, glass may be formed at a thickness exceeding a critical thickness L13 for capacitive sensing.

In this case, a separate capacitance sensor panel 131 may be positioned on the upper surface of the glass 132 in the production of the cooking plate.

That is, when it is difficult for the capacitance sensor panel to detect capacitance because the glass 132 is thick, the capacitance sensor panel 131 may be provided to be stacked on the upper surface of the glass.

In addition, in this case, the cooking plate may be formed by stacking a deterioration protection layer F on the upper surface of the capacitive sensor panel.

Specifically, the deterioration protective layer F may be formed by including a polymer material, such as a conductive inorganic material. In addition, when the cooking plate is formed in this way, the controller may apply a common voltage to the capacitance sensor panel electrodes in a section in which a touch is detected, to prevent image deterioration.

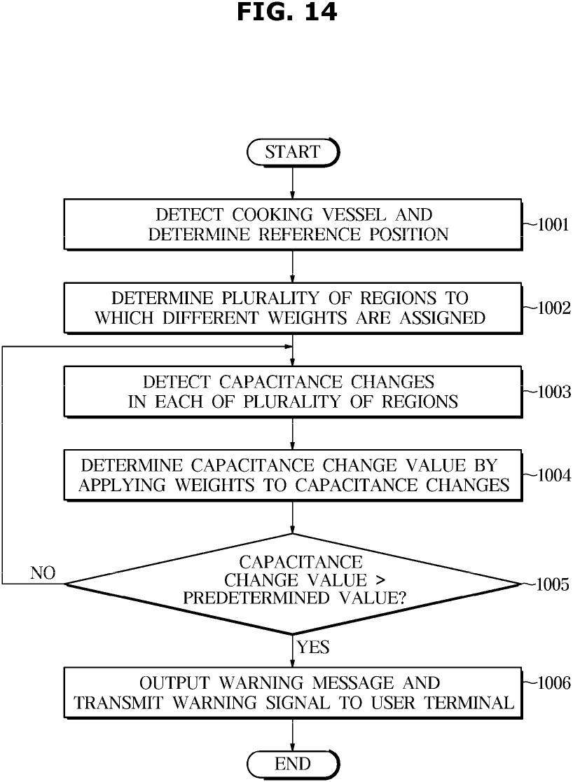

FIG. 14 is a flow chart according to an embodiment.

Referring to FIG. 14, the controller of the cooking apparatus may, in response to a cooking vessel being placed on the cooking plate, detect the cooking vessel and determine a reference position based on the cooking vessel (1001).

In addition, the controller may determine a plurality of regions to which different weights are assigned according to distances based on the position of the cooking vessel (1002). According to an embodiment, a region having a first radial distance from the reference position is a first region, and a first weight may be applied to a capacitance change in the corresponding region. In addition, a region having a second radial distance greater than the first radial distance is a second region, and a second weight may be applied to a capacitance change in the corresponding region.

Meanwhile, in this situation, the controller may detect capacitance changes in each of the plurality of regions (1003).

In addition, a capacitance change value may be determined by applying weights to the capacitance changes (1004).

Meanwhile, when the derived capacitance change value exceeds a predetermined value, the controller of the cooking apparatus may output a warning message and transmit a warning signal to the user terminal (1006). Thereafter, the cooking apparatus may reduce the output of the heater, or control the output of the heater through a user’s direct input of the cooking apparatus or an input through the user terminal.

Meanwhile, the disclosed embodiments may be embodied in the form of a recording medium storing instructions executable by a computer. The instructions may be stored in the form of program code and, when executed by a processor, may generate a program module to perform the operations of the disclosed embodiments. The recording medium may be embodied as a computer-readable recording medium.

The computer-readable recording medium includes all kinds of recording media in which instructions which can be decoded by a computer are stored, for example, a Read Only Memory (ROM), a Random Access Memory (RAM), a magnetic tape, a magnetic disk, a flash memory, an optical data storage device, and the like.

Although the present disclosure has been described with various embodiments, various changes and modifications may be suggested to one skilled in the art. It is intended that the present disclosure encompass such changes and modifications as fall within the scope of the appended claims.

What is claimed is:

1. A cooking apparatus comprising:
an alarm;
a cooking plate including glass and a capacitive sensor panel; and
a controller configured to:
determine a reference position corresponding to a position of a cooking vessel based on a capacitance change of the cooking plate,
determine a plurality of regions on the cooking plate to which different weights are assigned according to distances from the reference position, and
based on a value of the capacitance change of the cooking plate assigned with a weight exceeding a predetermined value, control the alarm to output a warning message.

2. The cooking apparatus of claim 1, wherein the controller is further configured to:
assign a first weight to a first region among the plurality of regions, and
assign a second weight less than the first weight to a second region formed at a distance greater than a distance of the first region from the reference position among the plurality of regions.

3. The cooking apparatus of claim 1, wherein the controller is further configured to:
determine a capacitance of the cooking plate corresponding to the cooking vessel as a reference capacitance, and
determine a value of a capacitance change of the cooking plate corresponding to each of the plurality of regions based on the reference capacitance.

4. The cooking apparatus of claim 1, wherein the controller is further configured to:
determine coordinate information corresponding to the cooking plate, and
associate the reference position and each of the plurality of regions with the coordinate information.

5. The cooking apparatus of claim 4, wherein the controller is further configured to:
obtain first coordinate information of a first point of the cooking plate in which the capacitance is changed at a first time point;
obtain second coordinate information of a second point of the cooking plate in which the capacitance is changed at a second time point later than the first time point; and
assign a higher weight to the second coordinate information than to the first coordinate information to determine the value of the capacitance change.

6. The cooking apparatus of claim 1, wherein the controller is further configured to determine a contact area of the cooking vessel as an area of the reference position based on the capacitance change of the cooking plate.

7. The cooking apparatus of claim 1, further comprising a heater provided below the cooking plate and provided to heat the cooking vessel,
wherein the controller is further configured to, in response to the value of the capacitance change exceeding a predetermined value, decrease an amount of output of the heater.

8. The cooking apparatus of claim 7, wherein the heater includes a plurality of induction heating coils, wherein the cooking vessel is a plurality of cooking vessels,
wherein the controller is further configured to:
determine the reference position and at least one induction heating coil corresponding to each of the cooking vessels based on the capacitance change of the cooking plate; and
in response to a value of the capacitance change corresponding to the at least one induction heating coil exceeding a predetermined value, decrease an amount of output of the at least one induction heating coil.

9. The cooking apparatus of claim 1, further comprising a communicator configured to communicate with a user terminal,
wherein the controller is further configured to, in response to the value of the capacitance change exceeding the predetermined value, transmit a warning signal to the user terminal.

10. The cooking apparatus of claim 1, further comprising a communicator configured to communicate with a user terminal,
wherein the controller is further configured to, in response to the value of the capacitance change exceeding the predetermined value, transmit an interface for controlling the cooking apparatus to the user terminal.

11. The cooking apparatus of claim 1, wherein the cooking plate includes:
the capacitive sensor panel stacked on an upper surface of the glass; and
a deterioration protection layer stacked on an upper surface of the capacitive sensor panel.

12. A method of controlling a cooking apparatus, the method comprising:
determining a reference position corresponding to a position of a cooking vessel based on a capacitance change of a cooking plate of the cooking apparatus;
determining a plurality of regions on the cooking plate to which different weights are assigned according to distances from the reference position; and
based on a value of the capacitance change of the cooking plate assigned with a weight exceeding a predetermined value, controlling an alarm of the cooking apparatus to output a warning message.

13. The method of claim 12, wherein the determining of the plurality of regions on the cooking plate includes:
assigning a first weight to a first region among the plurality of regions; and
assigning a second weight less than the first weight to a second region formed at a distance greater than a distance of the first region from the reference position among the plurality of regions.

14. The method of claim 12, wherein the determining of the value of the capacitive change of the cooking plate includes:
determining a capacitance of the cooking plate corresponding to the cooking vessel as a reference capacitance; and
determining a value of a capacitance change of the cooking plate corresponding to each of the plurality of regions based on the reference capacitance.

15. The method of claim 12, further comprising:
determining coordinate information corresponding to the cooking plate, and
associating the reference position and each of the plurality of regions with the coordinate information.

16. The method of claim 15, wherein the determining of the value of the capacitive change of the cooking plate includes:
obtaining first coordinate information of a first point of the cooking plate in which the capacitance is changed at a first time point;
obtaining second coordinate information of a second point of the cooking plate in which the capacitance is changed at a second time point later than the first time point; and
assigning a higher weight to the second coordinate information than to the first coordinate information to determine the value of the capacitance change.

17. The method of claim 12, further comprising:
determining a contact area of the cooking vessel as an area of the reference position based on the capacitance change of the cooking plate.

18. The method of claim 12, further comprising:
based on the value of the capacitance change exceeding a predetermined value, decreasing an amount of output of a heater provided below the cooking plate to heat the cooking vessel.

19. The method of claim 18,
wherein the cooking vessel is a plurality of cooking vessels,
the method further comprising:
determining the reference position and at least one induction heating coil corresponding to each of the cooking vessels based on the capacitance change of the cooking plate; and
in response to a value of the capacitance change corresponding to the at least one induction heating coil exceeding a predetermined value, decreasing an amount of output of the at least one induction heating coil.

20. The method of claim 12, further comprising:
in response to the value of the capacitance change exceeding the predetermined value, transmitting a warning signal to a user terminal.
